(19) United States
(12) Patent Application Publication
(10) Pub. No.: US 2003/0107987 A1
(43) Pub. Date: Jun. 12, 2003

(54) Reconfiguration system for a communication network

(76) Inventor: Gary A. Kinstler, Torrance, CA (US)

Correspondence Address: JOHN R. RAFTER, BOEING MANAGEMENT COMPANY, 15460 LAGUNA CANYON ROAD, IRVINE, CA, 92618, US

(21) Appl. No.: 10/011,124

(22) Filed: Dec. 7, 2001

(51) Int. Cl. G01R 31/08

(52) U.S. Cl. 370/228; 370/254

(57) ABSTRACT

A reconfiguration system for providing an interconnection capability for an IEEE-1394a or IEEE-1394-2000 based communication network. The reconfiguration system comprises an auxiliary connection system that includes a first port being connectable to a node of a first communication subnetwork and a second port being connectable to a node of a second communication subnetwork. Each of the ports has the capability of establishing or interrupting the sending and receiving of signals compliant with IEEE-1394a or IEEE-1394-2000 standards. A connecting subsystem of the auxiliary connection system relays the signals between the first port and the second port. A port manager system is operatively connected to the first port and the second port for managing the establishing or interrupting of the signals. A connection path is selectively provided between the first and second communication subnetworks to integrate these communication subnetworks into a common network.

### BACKGROUND OF THE INVENTION

1. Field of the Invention

This invention relates to wide band communication networks and, more particularly, to selectively providing auxiliary communication paths between subnetworks of such communication networks.

2. Description of the Related Art

The need for reliable connectivity between coordinating and communicating nodes of networks has long been a driving requirement in the design of networks in vehicle systems and for other critical communications functions, which support critical functions. Such networks often support the functions of distributed signal gathering and control processing for vehicle systems. The need for information to get through, even in the presence of network failures, is essential. The need therefore arises to provide alternative paths for critical data to move between critical nodes in the event of a failure in the primary communication path between two nodes. Prior typical networks have, in fact, run a redundant bus channel parallel to a primary channel to gain such redundancy, as is the case with the common MIL-STD-1553 databus.

The improved bandwidth performance and interconnect flexibility of modern high speed networks in recent years has brought with it some restrictions as to the topology, or configuration, with which such networks may be constructed. Depending upon their classes of service offered, some networks may be connected only in specific ways. These may include a single point-to-point connection, through crossbar switches or routers, as a linear network of multiple nodes stretched out along a single line, or with nodes converging into a combining hub, as configurations which require a loop type of topology, or a tree-looking type topology. The prior art of recent high bandwidth networks employing such topologies include, most recently for instance, Fibre Channel and the Universal Serial Bus, both of which are popular for computer, data storage, and desktop appliance networking. Popular topologies with Fibre Channel include the arbitrated loop (either hooked together daisy-chain style, or using hubs to interface individual connections to the main bus), or through cross-bar switches which provide one-to-one connections between individual nodes. Each of these prior art topologies require some kind of redundant connection if it is desired to provide link connectivity backup in the event of failure of the primary link path.

Some, such as the popular IEEE-1394-based bus (viz., IEEE-1394a and IEEE-1394-2000) explicitly impose restrictions against the connection as a “loop” topology. For buses with such restrictions against “loops” or other auxiliary connections, it would normally be necessary and comparatively expensive to implement a complete second, parallel bus, between nodes to gain the desired dual redundancy, as with the prior art alternative networks (e.g., Fibre Channel, Universal Serial Bus, etc.). In fact, the exclusion of the loop as a valid topology for IEEE-1394a and IEEE-1394-2000 based networks offers a unique advantage for those networks for creating a redundant connectivity path with a minimum of extra connectivity wiring (i.e., a single additional reconfigurable link), as compared to those networks which would require duplicating the entire primary network to obtain the same redundant connectivity.

It would be desirable to be able to selectively, as necessary, introduce one or more single link segments to recover from failure-induced topology breaks to restore the full operation of a primary network. Such would be highly preferable to having to run a full separate, completely redundant, parallel channel between all nodes. This invention is intended to address such a capability for networks, which would otherwise prohibit such redundant links.

### SUMMARY

The present invention is a reconfiguration system for providing an interconnection capability for an IEEE-1394a or IEEE-1394-2000 based communication network. The reconfiguration system comprises an auxiliary connection system that includes a first port being connectable to a node of a first communication subnetwork and a second port being connectable to a node of a second communication subnetwork. Each of the ports has the capability of establishing or interrupting the sending and receiving of signals compliant with IEEE-1394a or IEEE-1394-2000 standards. A connecting subsystem of the auxiliary connection system relays the signals between the first port and the second port. A port manager system is operatively connected to the first port and the second port for managing the establishing or interrupting of the signals. A connection path is selectively provided between the first and second communication subnetworks to integrate these communication subnetworks into a common network.

The present invention may provide a single-fault-and-still-operate capability, comparable to the dual redundant MIL-STD-1553 databus. A dual bus IEEE-1394 configuration implemented with this dynamic reconfiguration capability provides a triple-fail-and-still-operate capability between nodes.

### BRIEF DESCRIPTION OF THE DRAWINGS

FIG. 1 is a schematic illustration of a preferred embodiment of the reconfiguration system of the present invention shown integrated into a communication network.

FIG. 2 (Prior Art) shows a fully connected communication network under normal operation.

FIG. 3 is a detailed schematic illustration of the reconfiguration system of the present invention shown connected to the network of FIG. 2.

FIG. 4 depicts the most simplistic node interconnect using a single link of the reconfiguration system to form a reconfigurable loop configuration.

FIG. 5 shows a more robust implementation of the reconfiguration system into several links of a loop configuration to handle multiple failures.

FIG. 6 describes the process by which the reconfiguration system port management software and hardware work together to detect link faults and restore the network to full connectivity.

### DETAILED DESCRIPTION OF THE INVENTION

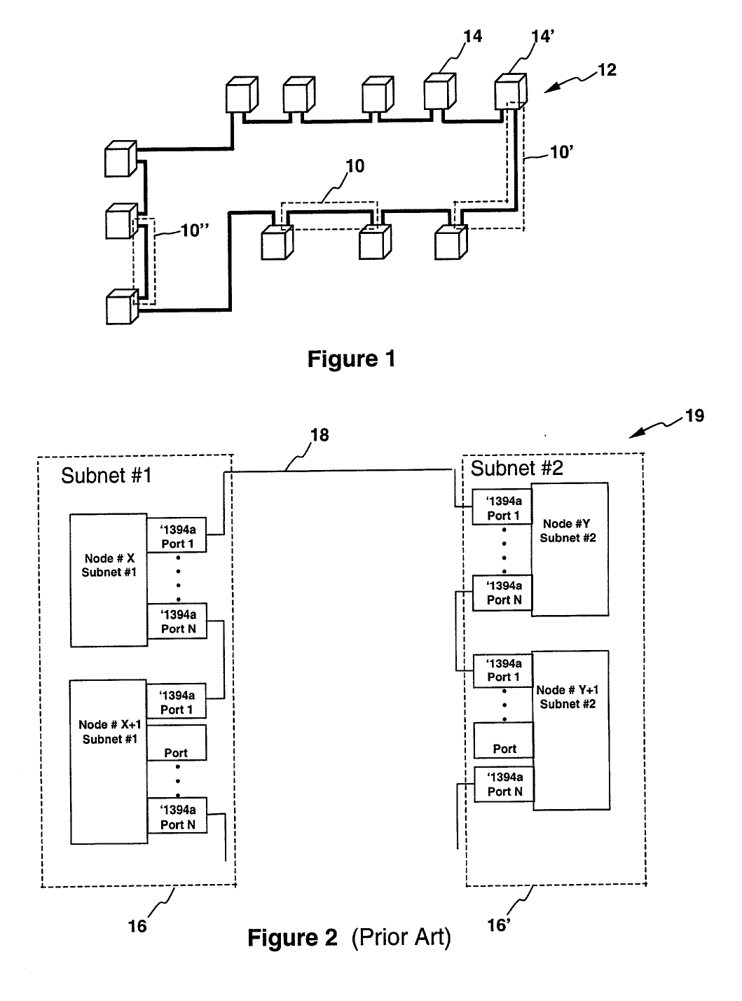

Referring to the drawings and the characters of reference marked thereon, FIG. 1 shows the reconfiguration systems of the present invention, designated generally as 10, 10′, 10″, shown connected in a communication network 12. The communication network 12 is typically a IEEE-1394a or IEEE-1394-2000 based communication network. However, the reconfiguration system may be used with other networks that may benefit from a dynamically connectable auxiliary connection system. The present invention is particularly beneficial for use with a 1394-based system, which prohibits the presence of a loop topology. As will be discussed below in detail, the reconfiguration system 10 of the present invention mitigates the effect of a connectivity fault arising from the loss of a normal connection.

The communication network 12 includes a plurality of nodes 14, 14′. Each node 14 has a minimum of two ports for connecting to the network topology. A node, may, for example, conduct processing of information derived from sensors and transformed into appropriate signals for driving actuators, effectors, etc.; gather and send sensor data to storage for health management, etc.

Referring now to FIG. 2 (Prior Art), two normally connected subnetworks 16, 16′ are shown connected by a nominal link 18. This forms a completely connected communication network 19. In the presence of a link failure, subnetworks 16 and 16′ become disconnected from each other. The term “subnetwork” as used herein is defined broadly to represent a portion or fragment of an otherwise complete network. Links between the network nodes may be subject to failure causing fragmentation of the complete network. It is desirable to re-establish this complete network.

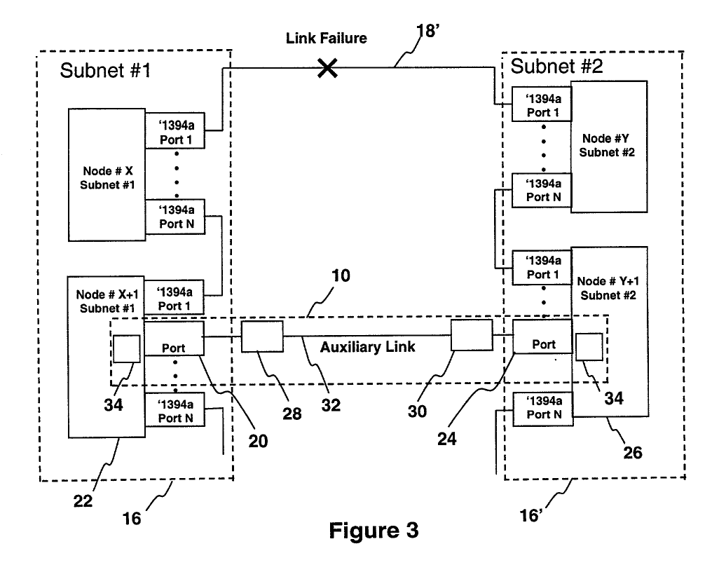

Referring now to FIG. 3, a reconfiguration system 10 is shown connected between two ports of nodes of the subnetworks 16 and 16′, respectively. The complete network has been fragmented into subnetworks 16, 16′ as a result of a failed link 18′. The reconfiguration system 10 includes an auxiliary connection system i.e. auxiliary link. The auxiliary connection system includes a first port 20 connectable to a node 22 of the first communication subnetwork 16.

A second port 24 of the auxiliary connection system is connectable to another node 26 of the second communication subnetwork 16′. Each port has the capability of establishing or interrupting the sending and receiving of signals compliant with IEEE-1394a or IEEE-1394-2000 standards.

A connecting subsystem of the auxiliary connection system includes converters or transducers 28, 30 and a connecting medium 32. The transducers 28, 30 may typically convert low voltage differential signals (LVDS) into photonic or RF transmission media. The transducers 28, 30 may be omitted if the LVDS is transmitted over copper wires. The connecting medium 32 may be, for example, a wire bi-directional harness, a bi-directional wireless communication link or a bi-directional photonic communication link.

A port manager system 34 of the auxiliary connection system is operatively connected to the first port 20 and the second port 24 for managing the establishment or interrupting of signals. The ports 20, 24 are electrically activated or disabled either under software control or by direct switch insertion under software control. The ports are, typically, LVDS signal drivers and receivers.

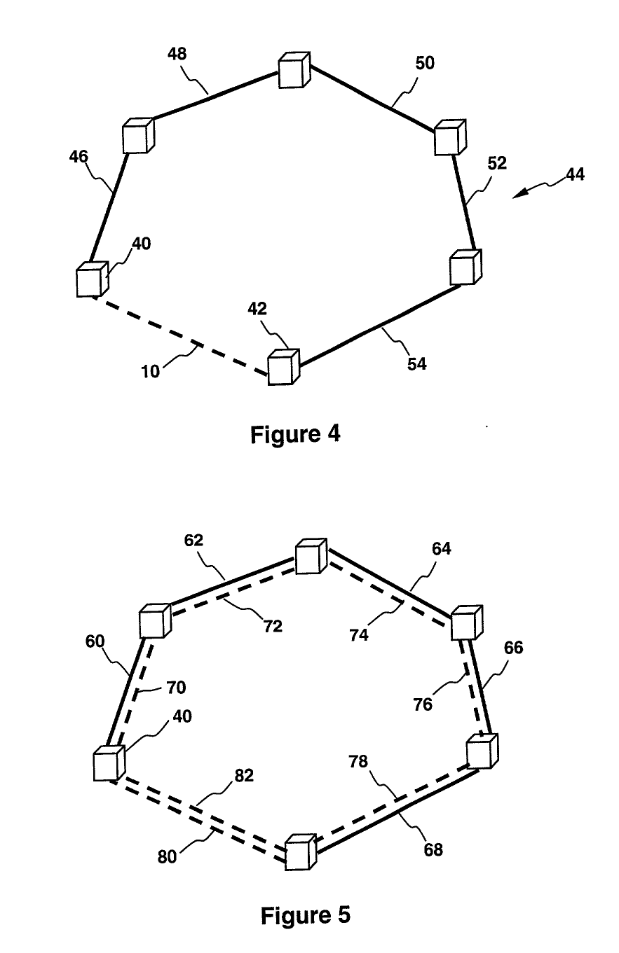

Referring now to FIG. 4, perhaps the most simplistic application of principles of the present invention is illustrated. This is the application of a single configuration system 10 between two nodes 40, 42 of an otherwise completely connected communication network, designated generally as 44. Under normal network operations, this auxiliary link will be disabled, establishing a valid IEEE-1394a or IEEE-1394-2000 topology. In the event of a failure of any of the interconnecting links 46-54, the enabling of the reconfiguration system 10 restores the network to a fully connected operational system.

Referring now to FIG. 5, a more robust application of the subject invention, is illustrated. Normally connected links 60-68 are shown in solid. Normally unconnected links 70-82 are shown in dashed lines. Utilization of this plurality of redundant link subsystems 70-82 accommodates multiple link failures.

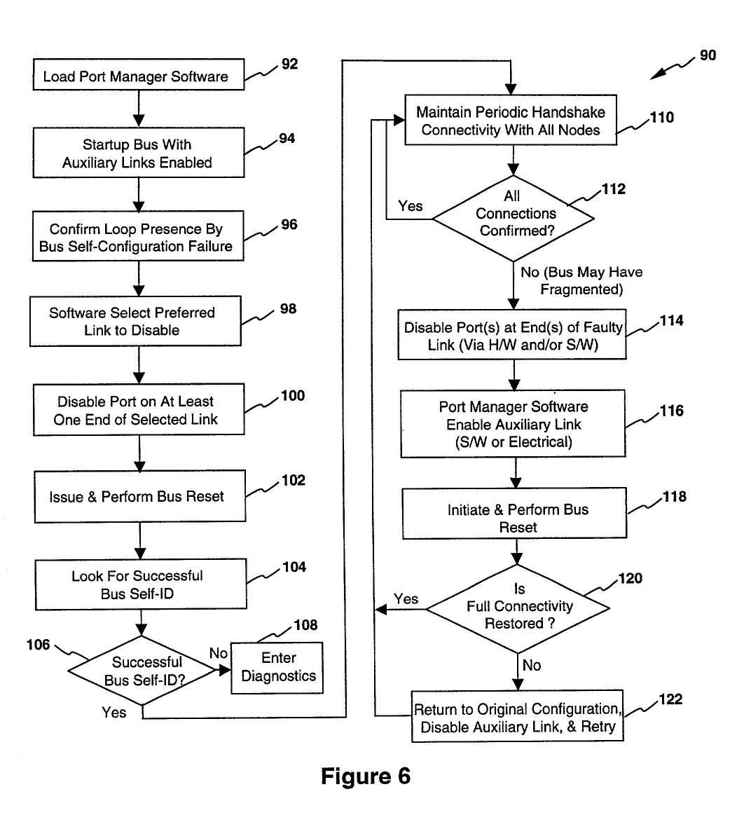

Referring now to FIG. 6, the operation of the port manager system is described. The functional block diagram 90 describes the initiation and maintenance of normal bus operations and recovery from a bus segmentation arising from a connection link failure using the features of the present invention. The monitoring of the bus health and enabling and disabling of auxiliary link(s) of the present invention are accomplished by a software-based port manager system residing within each node. The port manager system may be in, for example, a programmable logic device or a dynamically loadable microprocessor, with volatile and/or non-volatile memory portions. Each node maintains knowledge of the topology map of all the nodes in the system, with their respective capabilities. The port manager software is first loaded into each node, 92, whereafter the complete bus startup is initiated, with auxiliary links enabled 94. Doing so will create a loop configuration between some or all of the network nodes, representing an invalid configuration for IEEE-1394a or IEEE-1394-2000 based buses.

The presence of at least one such loop will subsequently be confirmed 96 by the failure of the bus to complete its self-identification process as evidenced by time-outs within the software, which monitors the progress through a bus reset. This step confirms the presence of at least one such functional auxiliary link. The port manager software, loaded with the preferred loop topology, selects 98 the auxiliary link to be disabled to establish a valid bus topology. Subsequently, it issues commands necessary to disable at least one end of the identified auxiliary link 100, and issues and performs a bus reset 102.

Following the bus reset, the port manager looks for a satisfactory completion of the bus self-identification process 104. If satisfactory self-ID has been achieved at decision point 106, the bus enters into normal operations at step 110. Otherwise, it enters a start-up diagnostic process 108. At step 110, the port manager initiates a monitoring function that confirms the continued connectivity of the full bus. This is accomplished by maintaining a periodic software handshake between all nodes, which is monitored simultaneously by the port manager software within all nodes on the bus. The presence or absence of the required handshakes is monitored to direct the flow of the software monitoring and recovery processes 112.

If and when any of the required handshakes fails to be maintained within an established monitoring interval, the software is directed to a link recovery process, which begins at step 114. The first step of the link recovery process is to disable, step 114, one or both ends of link which has been determined to be faulty, using software only, or dedicated hardware switches implemented to perform such enabling/disabling functions under the direction of software. The port manager software initiates the enabling of a new link, step 116, then initiates and performs another bus reset, step 118. The port manager software then determines whether the desired (e.g., full) bus connectivity has been restored 120. If it has, then control is returned to step 110 without any further software action to continue to maintain handshake connectivity monitoring between all nodes. If the reconfiguration of the bus with the auxiliary link enabled failed to reestablish the desired connectivity, then it shall be presumed that replaced link was probably good. In that case, control is passed to step 122 where the original link configuration is restored and then control is returned back to step 110 for further monitoring. The steps of 110 through 120 or 110 through 122 will continuously be cycled as necessary to maintain a satisfactory link configuration.

The process described in the process 90 of FIG. 6 represents the case for the most simplistic case implementation of the present invention as depicted in FIG. 4. In a similar manner, multiple auxiliary link configurations as depicted in FIG. 5 may be implemented with replicated portions of the software of process 90 for those respective links.

Thus, while the preferred embodiments of the devices and methods have been described in reference to the environment in which they were developed, they are merely illustrative of the principles of the inventions. Other embodiments and configurations may be devised without departing from the spirit of the inventions and the scope of the appended claims.

1. A reconfiguration system for providing an interconnection capability for an IEEE-1394a or IEEE-1394-2000 based communication network, comprising:
an auxiliary connection system, comprising:
a) a first port being connectable to a node of a first communication subnetwork;
b) a second port being connectable to a node of a second communication subnetwork, each said port having the capability of establishing or interrupting the sending and receiving of signals compliant with IEEE-1394a or IEEE-1394-2000 standards;
c) a connecting subsystem for relaying said signals between said first port and said second port; and
d) a port manager system operatively connected to said first port and said second port for managing said establishing or interrupting of said signals,
wherein a connection path is selectively provided between said first and second communication subnetworks to integrate these communication subnetworks into a common network.

2. The reconfiguration system of claim 1, wherein said auxiliary communication system comprises means for connecting two communication subnetworks that were previously connected by an operative IEEE-1394a or IEEE-1394-2000 connection that is no longer operative.

3. The reconfiguration system of claim 1, wherein said auxiliary connection system comprises means for connecting two communication subnetworks that were previously unconnected.

4. The reconfiguration system of claim 1, wherein said capability of establishing or interrupting said signals is provided by electrical switches of said ports under the direction of said port manager system.

5. The reconfiguration system of claim 1, wherein said capability of establishing or interrupting said signals is provided by software functionality implemented within said ports under the direction of said port manager system.

6. The reconfiguration system of claim 1, wherein said connecting subsystem comprises a bi-directional wire harness.

7. The reconfiguration system of claim 1, wherein said connecting subsystem comprises a bi-directional wireless communication link.

8. The reconfiguration system of claim 7, wherein said connecting subsystem further comprises a converter connected to said bi-directional wireless communication link for producing IEEE-1394a or IEEE-1394-2000 compliant electrical signals.

9. The reconfiguration system of claim 1, wherein said connecting subsystem comprises a bi-directional photonic communication link.

10. The reconfiguration system of claim 9, wherein said connecting subsystem further comprises a converter connected to said bi-directional photonic communication link for producing IEEE-1394a or IEEE-1394-2000 compliant electrical signals.

11. The reconfiguration system of claim 1, wherein said port manager system, comprises software for performing the following steps:
a) determining that a successful bus self-identification has been achieved;
b) maintaining a periodic software handshake between all nodes of said first and second subnetworks;
c) determining whether the handshakes have been performed; and,
d) providing a link recovery process if there is an absence of a handshake.

12. The reconfiguration system of claim 11, wherein said link recovery process, comprises:
a) disabling a port of a link that has been determined to be faulty;
b) enabling a new link;
c) initiating and performing a bus reset; and,
d) determining whether bus connectivity has been restored.

13. The reconfiguration system of claim 1, wherein said node of said first communication subnetwork and said node of said second communication subnetwork are normally not connected during normal network operations.

14. The reconfiguration system of claim 1, wherein said node of said first communication subnetwork and said node of said second communication subnetwork are normally connected by means other than said auxiliary connection system during normal network operations, said auxiliary connection system providing a redundant link in the event of a single link failure.

15. A method for providing an interconnection capability for an IEEE-1394a or IEEE-1394-2000 based communication network, comprising the steps of:
a) providing two IEEE-1394a or IEEE-1394-2000 communication subnetworks;
b) inserting an auxiliary connection system between one node of each said communication subnetwork, said auxiliary connection system being enableable under desired reconfiguration conditions; and
c) enabling said auxiliary connection system, under said desired reconfiguration conditions, to provide a connection path,
wherein said two subnetworks are thereby integrated into a common network.

16. The method claim 15, wherein said step of inserting an auxiliary connection system comprises connecting two communication subnetworks that were previously connected by an operative IEEE-1394a or IEEE-1394-2000 connection that is no longer operative.

17. The method claim 15, wherein said step of inserting an auxiliary connection system comprises connecting two communication subnetworks that were previously unconnected.

18. The method claim 15, wherein said step of enabling said auxiliary connection system comprises the steps of:
a) determining that a successful bus self-identification has been achieved;
b) maintaining a periodic software handshake between all nodes of said first and second subnetworks;
c) determining whether the handshakes have been performed; and,
d) providing a link recovery process if there is an absence of a handshake.

19. The method claim 18, wherein said link recovery process comprises the steps of:
a) disabling a port of a link that has been determined to be faulty;
b) enabling a new link;
c) initiating and performing a bus reset; and,
d) determining whether bus connectivity has been restored.
